(19) United States
(12) Patent Application Publication
(10) Pub. No.: US 2025/0267798 A1
(43) Pub. Date: Aug. 21, 2025

(54) PRINT ON MASK AND PRINT ON CORE METHODS FOR 3D PRINTED CIRCUIT STRUCTURES

(71) Applicant: LCP MEDICAL TECHNOLOGIES, LLC, Rogers, MN (US)

(72) Inventor: James Rathburn, Rogers, MN (US)

(21) Appl. No.: 19/047,284

(22) Filed: Feb. 6, 2025

Related U.S. Application Data
(63) Continuation-in-part of application No. PCT/IB2025/050329, filed on Jan. 11, 2025.
(60) Provisional application No. 63/619,778, filed on Jan. 11, 2024.
(60) Provisional application No. 63/550,685, filed on Feb. 7, 2024.

(51) Int. Cl. H05K 3/12; H05K 1/02; H05K 1/03; H05K 1/09; H05K 1/11; H05K 1/18; H05K 3/30

(52) U.S. Cl. CPC H05K 3/125; H05K 1/028; H05K 1/0393; H05K 1/092; H05K 1/113; H05K 1/181; H05K 1/186; H05K 3/1283; H05K 3/303; H05K 2201/09563; H05K 2201/10121; H05K 2203/166

(57) ABSTRACT

A method of creating a printed circuit board (PCB) is provided. The method includes a core having one or more fiducials thereon. The core includes a first one or more circuit structures. One or more components of a printer are aligned with the one or more fiducials based on one or more images captured of the core with an optical camera of the printer. A first dielectric layer is printed on a first side of the core. A second one or more circuit structures in the first dielectric layer. Printing a second dielectric layer on a second side of the core, the second side reverse of the first side. Printing a third one or more circuit structures in the second dielectric layer on the second side of the core.

### RELATED APPLICATIONS

This application is a continuation-in-part of International Patent Application No. PCT/IB2025/050329, filed Jan. 11, 2025, which claims the benefit of U.S. Provisional Application No. 63/619,778, filed on Jan. 11, 2024, both of which are entitled “HIGH-PERFORMANCE, LOW SIGNAL LOSS, HIGH-DENSITY, MULTI-LAYER, DOUBLE-SIDED 3D PRINTED CIRCUIT STRUCTURE DEPOSITION AND FABRICATION PLATFORM”, and this application claims the benefit of U.S. Provisional Application No. 63/550,685, filed on Feb. 7, 2024, entitled “PRINT ON MASK AND PRINT ON CORE 3D PRINTED CIRCUIT STRUCTURES”, the contents of which are hereby incorporated herein by reference.

### BACKGROUND

Traditional printed circuits are often constructed in what is commonly called rigid or flexible formats. The rigid versions are used in nearly every electronic system, where the printed circuit board (pcb) is essentially a laminate of materials and circuits that when built is relatively stiff or rigid and cannot be bent significantly without damage. Flexible circuits have become very popular in many applications where the ability to bend the circuit to connect one member of a system to another has some benefit. These flexible circuits are made in a very similar fashion as rigid pcbs, where layers of circuitry and dielectric are laminated. The main difference is the material set used for construction. Typical flexible circuits start with a polymer film that is clad, laminated, or deposited with copper. A photolithography image with the desired circuitry geometry is printed onto the copper, and the film is etched to remove the unwanted materials. The films are processed similarly to that of rigid pcbs with a series of imaging, masking, drilling, via creation, plating, trimming etc. The resulting circuit is flexible in such a way that as it is bent, the polymer film bends and supports the copper circuitry in a way that it does not crack or break. These circuits are solderable, and can have devices attached to provide some desired function. They are very commonly used in many electronic systems such as notebook computers, medical devices, displays, handheld devices, autos, aircraft and many others. These flexible materials can be used in high-frequency applications where the material set and design features can often provide better electrical performance than a comparable rigid circuit. These circuits are connected to the system in a variety of ways. In most cases, a portion of the circuitry is exposed to create a connection point in terminal. Once exposed, the terminal can be connected to another circuit or component by soldering, conductive adhesive, thermos-sonic welding, pressure or some sort of connector. In general, the terminals are located on an end of the circuit, where edge traces are exposed or in some cases an area array of terminals are exposed. Often there is some sort of mechanical enhancement at or near the connection to prevent the joints from being disconnected during use or flexure. Rigid printed circuits are the backbone of all electronic systems, with many devices soldered to terminals on the pcb.

Most printed circuit constructions utilize dielectrics and composites in sheet or film form, with processing steps that rely on lamination and bonding materials in sheet form to create the multi-layer circuit stacks. As circuits and the spaces between them get smaller, it becomes increasingly difficult to control the impedance environment of the circuits. The characteristic impedance of a circuit is dictated by the circuit geometry itself, the dielectric properties of the material set surrounding the circuit, and the dielectric separation to the nearest reference plane. The use of conventional material sets commercially available are typically provided in specific thickness that is held to a certain tolerance that may be a fairly wide range depending on manufacturing variability. These material sets can also be relatively thick due to the desire for ease of handling during the manufacturing process. In some cases, a build-up film such as ABF is used for fine line and space substrate applications, where the circuit pattern is laser ablated into the film and plated with electroless copper then electrolytic copper to create the circuit pattern. In this case, the dielectric film itself acts as the base dielectric and does not require a bonding layer with the next layer of ABF serving as the next layer of dielectric. ABF is one alternative that uses itself as the dielectric bearing circuits, with Liquid Crystal Polymer and PTFE of Teflon among other materials as well as many other lower loss materials that are a mixture of resin, epoxy, ceramic, glass etc. The subject matter discussed herein leverages the principles of traditional circuit fabrication, with a hybrid approach using alternate low loss materials in liquidous or dielectric ink form to create a multi-layer low loss circuit stack that has advantages over traditional methods.

A relatively recent approach to printed circuit fabrication is called Additive Manufactured Electronics (AME) or 3D Printed Circuits. This approach leverages the significant investment and advancement of 3D printed polymers and metals where a printer platform deposits materials in desired locations driven by a computer generated model of the desired part or component. The printer software basically slices the desired model into thin layers similar to that of traditional printed circuit fabrication layers, and the printed system uses a variety of methods to deposit polymers and or metals in the desired locations on each layer with a sequential deposition that results in the desired part. A variety of methods are used for deposition, with some being extrusion of solid filament or pellet polymers, liquid resin vats that are solidified with a laser, as well as powder materials that are sintered by a laser or have a binder material that is cured by a laser.

The 3D printed circuit version of this printing process is typically accomplished by a printer platform that has an inkjet, dispenser, or aerosol jet head that deposits dielectric insulator materials in desired locations, and particle based conductive metal ink where an arrangement of small metal spheres or flakes are suspended in an ink or liquidous solution that can be printed and then processed to create a conductive circuit trace. These printer platforms leverage digital tool path files that indicate what material to place where on a given layer, and indexes in the Z direction to deposit the next layer with the resultant intent of growing or adding dielectrics and metal conductors layer by layer to create or simulate a circuit stack that resembles a printed circuit board fabricated by conventional methods.

In general, the 3D printer platforms deposit liquid dielectric and particle bearing metallic inks onto a build plate of some sort, and rely on a variety of processing methods to cure or solidify the inks post deposition. Dielectric inks are typically cured with UV exposure in 365 to 405 nm wavelength, or a thermal cure to solidify the ink in position with a desired pattern. Metallic inks are typically particle based where the carrier medium is either cured by UV exposure or thermally processed to either cure the binder, drive off any solvent or carrier medium or sinter the particles with a laser, heat or photonic blast that heats the metal quickly without damaging the surrounding dielectric material.

In general, printing systems are somewhat defined by the viscosity of the materials to be deposited. Inkjet materials are a common deposition method with low viscosity materials typically required to pass through ink jet heads without clogging. Dispensing or extruding of higher viscosity inks or pastes is a common method, and some systems use a atomization or aerosol method to create a jet able stream of low to medium viscosity materials. Various systems contain the deposition method as well as common curing methods within the platform, while some systems focus on printing with post processing performed in a supporting system that requires the printed material to be removed from the printer and placed into the supporting system such as a UV lamp station, thermal curing oven, photonic cure system etc.

The advantages of 3D printed circuits are typically the physical time needed to create a circuit product with the ability to digitally print a desired circuit rather than go through the conventional lamination, print, etch, laser drill processes required when using a sheet or panel based traditional circuit fabrication process. The material usage is an advantage as only the desired materials are deposited, and the extensive chemical processing and waste treatment associated with conventional printed circuit production are eliminated.

The available commercial systems are typically used for prototype applications or research activities while the industry has not evolved far enough yet to provide commercial production of 3D printed circuits as a replacement for conventional laminated printed circuit construction. This situation is driven primarily by the level of performance achievable with 3D printed circuits is not on par with conventional circuit fabrication, and the material sets with positional accuracy of the printing process typically much lower tolerance than conventional methods. There are also several limitations related to the material sets and printing methods that have historically limited 3D printed circuit applications to large geometry circuits, with few layers and negative impact to circuit conductivity due to the particle based inks.

### BRIEF DESCRIPTION

A method of creating a printed circuit board (PCB) is provided. The method includes a core having one or more fiducials thereon. The core includes a first one or more circuit structures. One or more components of a printer are aligned with the one or more fiducials based on one or more images captured of the core with an optical camera of the printer. A first dielectric layer is printed on a first side of the core. A second one or more circuit structures in the first dielectric layer. Printing a second dielectric layer on a second side of the core, the second side reverse of the first side. Printing a third one or more circuit structures in the second dielectric layer on the second side of the core.

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 is a block diagram illustrating components of an example 3D printer;

FIG. 2 is a block diagram illustrating components of another example 3D printer;

FIG. 3 is a block diagram illustrating components of yet another example 3D printer;

FIGS. 4A and 4B are cross-sectional views of respective examples of a basic 3D printed circuit structure printed by existing printer platforms;

FIG. 5 is a cross-sectional view of example stages in printing of a basic 3D circuit structure using any of the platforms of FIGS. 1-3;

FIG. 6 is a cross-sectional view of example stages in printing a circuit structure with particle-free metal ink using any of the platforms of FIGS. 1-3;

FIG. 7 is a cross-sectional view of example stages in printing a circuit structure with both particle-based metal ink and particle-free metal ink;

FIG. 8 is a cross-sectional view of another example circuit structure, in which the platforms of FIGS. 1-3 provide a hybrid approach where the particle-free metal inks are used as an electroplating catalyst or seed layer to initiate conventional electrolytic plating or enhance electroless plating;

FIG. 9 is a cross-sectional view of an example stage in a process of printing using the platforms of FIGS. 1-3;

FIGS. 10A and 10B are cross-sectional views of example circuit structures printed with any of the platforms of FIGS. 1-3 to create an extremely flat print surface as the precision if the deposition is a key aspect of the platform;

FIGS. 11A and 11B are cross-sectional views of example stages in printing circuit structures with the platforms of FIGS. 1-3;

FIGS. 12A and 12B are cross-sectional views of other example stages in creating a circuit structure using the platforms of FIGS. 1-3;

FIGS. 13A and 13B are cross-sectional views of other example circuit structures created using the Print on Mask principle;

FIG. 14 is a cross-sectional views of example stages in printing coaxial and twin axial signal lane structures;

FIG. 15 is a cross-sectional views of example stages in printing a coaxial structure with a vertical transition;

FIG. 16 is a cross-sectional view of another example structure printed with the platforms of FIGS. 1-3 that includes a lane with an optical polymer dielectric to create an embedded optical transmission line;

FIGS. 17A and 17B are cross-sectional views of example circuit structures created with the platforms of FIGS. 1-3 illustrating a very basic example of mounting embedded devices on an internal circuit layer within the circuit stack;

FIG. 18 is a top view of an example of an outer/exposed surface of an existing circuit structure to which additional layers can be added using the Print on Mask process described herein; and

FIGS. 19A and 19B are top views of example rigid-flex PCBs created using the Print on Core process described herein.

### DETAILED DESCRIPTION

The subject matter discussed herein is focused on overcoming the limitations of 3D printed circuit fabrication and provide a platform, material set and circuit structure fabrication techniques to advance 3D printing to a commercial level that enables high performance, low signal loss at multi-GHz frequencies, high circuit density in high layer count circuit stacks with a customizable 3D printing platform utilizing specially designed inks and methods. To achieve the level of precision and performance desired for next generation circuits and systems, a fabricator today needs to use multiple printer systems and multiple post processing methods to achieve circuit constructions that are comparable or exceed the capability of conventional laminated printed circuit construction. The subject matter discussed herein discloses a unique printing platform that combines multiple functions currently provided in multiple standalone systems and post processing methods into one configurable system that is specially designed with an architecture focused on creating very precise high-performance circuits with multiple layers. The subject matter discussed herein also provides unique methods and capabilities that leverage a hybrid application of conventional printed circuit fabrication with the advantages of 3D printed circuit fabrication and material deposition, with structures that aim to provide performance and reliability on par or exceeding conventional methods. The deposition platform itself has the unique potential to replace or take the place of the many equipment sets and processing requirements related to conventional printed circuit fabrication within a factory process flow. The subject matter discussed herein is also intended to provide a focused unique alternative to 3D printed electronics printers and systems currently available in the market.

Traditional methods of printed circuit fabrication typically utilize a dielectric in sheet form, that is bonded with a lamination process that applies heat and pressure to the material stack to provide a reliable bond between the layers. If circuits are present on the dielectric sheets and standing proud of the surface, the bonding process is such that the bond materials must flow enough to fill in between the circuit traces while creating a strong enough bond to provide a reliable circuit stack that does not separate or delaminate. This lamination process often requires a vacuum environment to remove any air from the process such that entrapment is avoided which can cause delamination points. The high temperature and pressure can also add stress to the circuit stack which can result in bowing or out of flat conditions during subsequent processing or final assembly with solder reflow. Another limitation of traditional laminated circuit stacks relates to the creation of vertical connections called vias, where the dielectric must be drilled or laser ablated to create a spot for vertical electrical connections to be plated with copper.

3D printed circuit fabrication has many advantages over conventional printed circuit fabrication, but also has several limitations that have prevented more widespread use in end products. 3D printed circuits today are often used to create quick prototypes to test or validate some desired function, with a transition to conventional circuit fabrication for production. The most significant limitation has been the material sets used to create the conductive metal circuits, layer to layer vias, and solderable surface mount terminations. The conductive inks have typically been a particle-based solution with a percentage of metal content within a liquid medium that allows for printing deposition. The electrical conductivity is created by the small metal particles, usually silver, gold or in some cases copper, touching each other at some point within the matrix to create a conductive path. This conductive path has typically been only a fraction of the conductivity of a comparable circuit made from bulk copper for example. The binder materials are non-conductive, and the touching points between the particles or flakes are only a small percentage of the bulk material resulting in a resistivity that is much higher than bulk plated or etched metal. The conductors are also very “rough” from a surface finish standpoint and those issues combined make these circuits not acceptable for higher performance applications. This situation has limited the use of 3D printed circuits to either low performance applications or basic R&D efforts and prototypes. The subject matter discussed herein provides metal ink deposition and processing methods within the platform to mitigate the limitations of particle based metallic inks such that the use of the platform and material set results in high performance circuit structures comparable to conventional circuit fabrication and similar bulk resistivity of metal conductors.

Another material limitation is the dielectric inks used for insulating and separating the conductors. In many cases a UV cured ink is used to print the dielectrics and the composition that makes the material UV curable can often be very lossy from a signal integrity standpoint. These materials can also have a lower temperature tolerance than required for lead-free soldering of components to the final assembly, requiring low temperature solders or conductive adhesives for component attachment.

Another material limitation is the nature of printing or depositing a liquid material in a desired location with accuracy and precision with a tradeoff being that liquid tend to saturate, spread or wet the surface being printed. Low viscosity inks are easier to print with ink jet heads, while thicker viscosity inks that tend to stay in place better than low viscosity inks are best deposited with a dispensing or extruding head that apply a bead of material based upon the nozzle size and pressure applied. Aerosol print head are cable of depositing a variety of viscosities in a very precise manner but have relatively small deposition points and are not well suited for larger print areas.

A limitation of 3D Printed circuits is often the printing systems themselves. Inkjet systems are the most prevalent, and the nature of inkjet deposition requires small dots of material to be deposited in a desired pattern such that they overlap or touch each other. This method as well as the apertures of the print nozzles limits the resolution of deposition to approximately 25 microns for some materials and often 50, 75 100 microns for some materials. Dispensed or extruded materials are typically higher viscosity and lower resolution but can deposit a larger volume of material than inkjet. Aerosol has higher resolution in the 10 micron range, but is relatively slow as the deposition volumes are small compared to the speed of ink jet and the volume of material in dispensing applications. The subject matter discussed herein provides a multi-head or multi-deposition method architecture that combines the best aspects of each deposition method co-located in the same platform.

A limitation of the 3D printing methods is based upon the fact that the materials cannot be deposited in air so to speak and they need to be deposited onto something. Most printing methods deposit the material onto a substrate or sheet of material such as polyimide, polyester, glass, paper etc. that is placed into the printer and held in place often with a vacuum table. In some cases a build plate is used and the material is deposited onto the build plate, typically a layer of base dielectric that mimics the deposition onto a substrate. This method relegates the typical 3D printed circuits to be a non-conductive base layer with metal conductors and subsequent dielectric layers printed up to create the desired circuit stack with exposed metal terminations for component attachment in a one sided circuit. The subject matter discussed herein provides a platform, material set and structure creation method that enables exposed component terminations on both sides of the final 3D printed circuit.

Another limitation of the 3D printed circuit platforms is they are high cost, and typically focused on one type of deposition method and in some cases post processing operations within the system such as UV cure, photonic cure, thermal cure, or laser sintering. These systems are also often defined by the printing or deposition process of choice, which dictates the material sets that can be used and the resultant structures that can be printed. These deposition methods, material sets choices, and post processing needs drive the overall 3D printed circuit structures that can be created and require multiple supporting systems needed to create circuits that are typically low performance yet still provide some value.

The subject matter discussed herein provides a unique approach to a 3D printed circuit fabrication platform that is driven by a unique set of high performance materials, the deposition methods needed to print high performance low loss circuits with multiple layers, with exposed surface mount termination layers both sides, as well as precision supporting processes within the system to enable a printed circuit factory like capability in one platform. There is no system, material set, or processing method available today that provides all of these capabilities and the proposed invention provides a multi-option platform unique to the 3D printing industry.

The subject matter discussed herein includes a 3D Printed Circuit Fabrication platform that combines the deposition methods, tool set, post processing techniques to create a unique system not available in the marketplace today. In general terms, the platform is defined as a combination of baseline functions with optional tools added to the baseline configuration to provide a lower cost entry point Platform I, a midpoint Platform II and Platform III Advanced with options to add functionality.

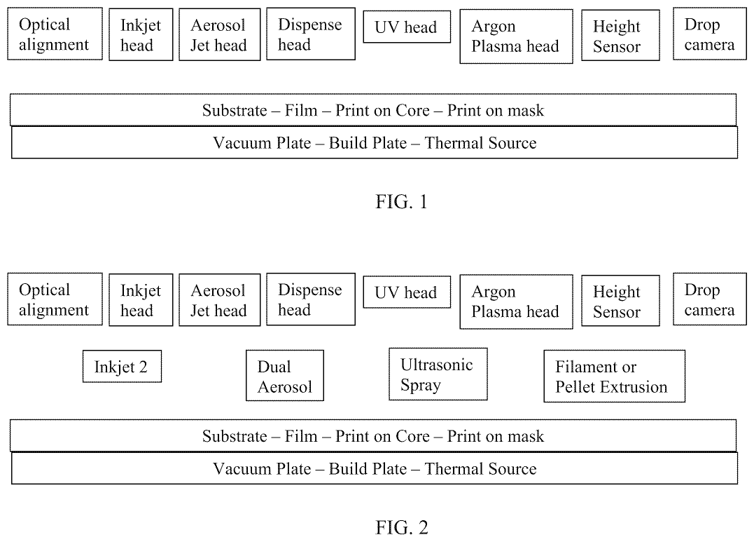

FIG. 1 is a block diagram illustrating components of the baseline Platform I. The Baseline Platform I architecture is a self-contained platform desk or table-top sized that consists of a vacuum table base with thermal capabilities to heat the substrate and subsequent deposited materials in the event a thermal cure is desired. The system has:
An optical alignment camera to allow for precision alignment of tools to the print area and localized adjustment to features on the substrate or printed features.
A precision inkjet head is present for deposition of thin layers over a large area,
An aerosol print head for precision deposition in focused fine feature regions,
A dispense head for deposition of higher viscosity or larger volume regions
A UV source to cure inks
An Argon-Argon/Hydrogen plasma head to cure particle free metallic inks
A height senor to enable precision Z direction deposition Control
A drop watch camera to enable precision tuning of the material deposition

FIG. 2 is a block diagram illustrating components of the mid Platform II, which includes the Baseline Platform I configuration plus additional functions and options. Platform II includes:
Base Build platform I plus additional inkjet and aerosol capabilities to deposit metal and dielectric without change of materials in a single head.
Ultrasonic spray for large area deposition in precision coating depth
Filament—pellet extrusion head capable of precision X,Y,Z deposition of high temperature thermoplastics such as Liquid Crystal Polymer, Abs, PEEK, PEI-Ultem

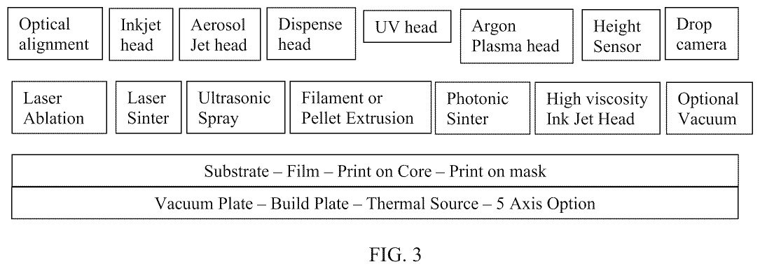

FIG. 3 is a block diagram illustrating components of the Advanced Platform III, which includes the Baseline Platform I configuration plus additional functions and options. Platform III includes:
Base Build platform I with 5 axis motion control for contour surface printing
A UV or Pico-second laser source for ablation of dielectric. Possible metal, possible sinter
A fiber laser source for ink sinter
Ultrasonic spray for fine controlled wide area dielectric or metal ink coverage
A filament or pellet extrusion head capable of printing Liquid Crystal polymer thermoplastic
A photonic cure source for sintering of metal inks
High Viscosity Inkjet Head-up to 200 cp
Vacuum chamber options to avoid oxide generation of copper inks

All of these platforms include one or more controllers with an appropriate software suite to control and manage the various operations an functions within the platform.

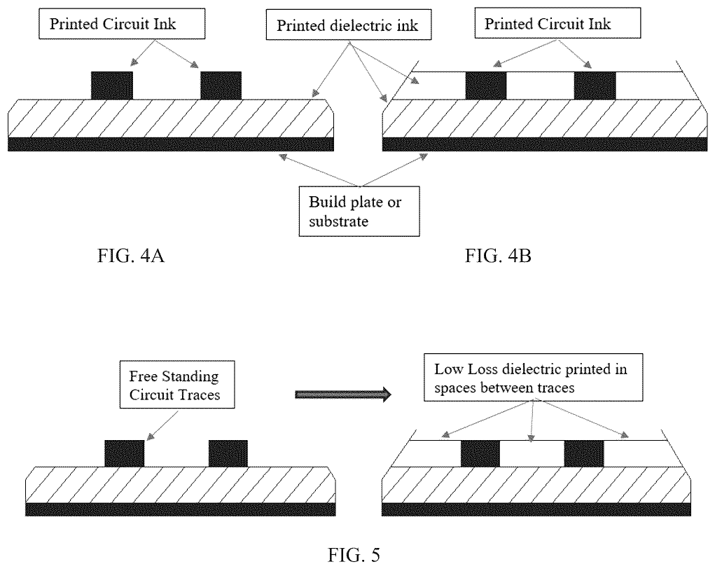

FIGS. 4A and 4B are cross-sectional views of respective examples of a basic 3D printed circuit structure printed by existing printer platforms. FIG. 4A includes a base dielectric printed onto the build plate or build substrate and conductive metal ink circuits or traces printed on the desired pattern onto the substrate. The spaces between the traces are then printed with dielectric to complete that layer. FIG. 4B includes the second basic construction with dielectric printed onto the substrate and further dielectric printed on the desired pattern to create a trench or groove within the dielectric layer such that the conductive metal ink is printed into the trench and cured or sintered to create the desired electrical circuit trace. This process is repeated if possible, with vertical connections called vias printed onto the trace.

FIG. 5 is a cross-sectional view of example stages in printing of a basic 3D circuit structure using any of the platforms of FIGS. 1-3. These platforms are aimed at the use of low loss dielectric materials in liquidous or ink form to provide an alternative or compliment to conventional film or sheet dielectric multi-layer circuit fabrication. The advancement of 3D printing, ink jet printing, aerosol jet printing and spray coating has enabled an opportunity to utilize low loss dielectric materials for printed circuit fabrication. As circuit geometries get smaller and resulting dielectric thickness layers need to get thinner to accommodate impedance matching environments, the ability to deposit low loss dielectric in a controlled manner in thin deposition has advantages over conventional film lamination techniques. In addition, many low loss liquid or ink dielectrics can be loaded with particles to enhance electrical or mechanical properties. A significant advantage with deposition of low loss dielectric ink or liquidous materials is the natural filling of spaces between circuit traces without the need for heat and pressure lamination required for traditional circuit leveling or filling between circuit traces that may have a high aspect ratio and difficult to fill with a lamination process.

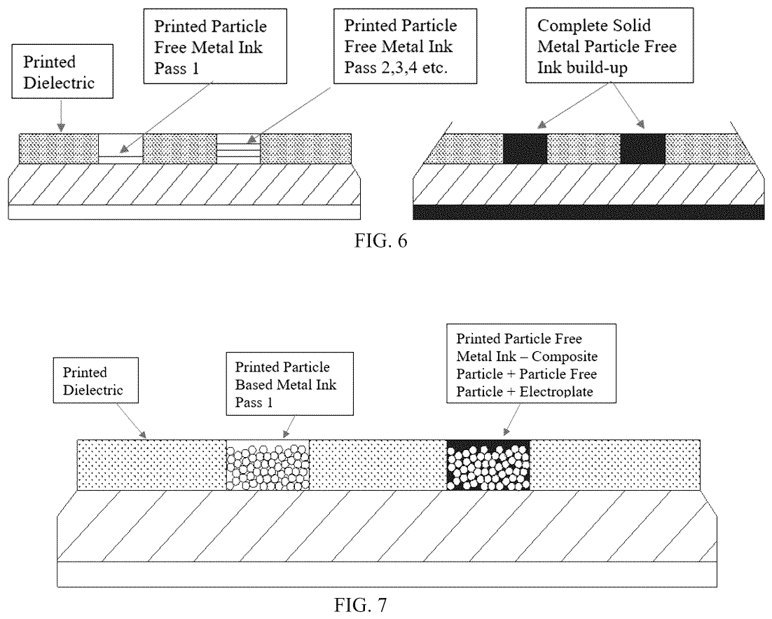

FIG. 6 is a cross-sectional view of example stages in printing a circuit structure with particle-free metal ink using any of the platforms of FIGS. 1-3. The platforms can print with particle-free metal inks that when printed (left cross-section of FIG. 6) and cured (right cross-section of FIG. 6) create a contiguous metal layer similar to that of electroless or electrolytic plating without the need for plating chemistry and equipment sets. Particle-free metal ink is a liquid that includes metal ions, metal molecules, and/or metal salts along with volatile solvents in a solution. The metal ions, molecules, and/or salts can include copper and/or palladium and have a size less than 1 micron.

FIG. 7 is a cross-sectional view of example stages in printing a circuit structure with both particle-based metal ink and particle-free metal ink. The platforms of FIGS. 1-3 can use particle-based metal inks (left cavity of FIG. 7) and can combine the bulk deposition of particle-based inks with particle free inks to fill the gaps between particles or create a much smoother conductor surface (right cavity of FIG. 7). Particle-based metal inks are inks having particles larger than 1 micron. In some cases, multiple layers or passes of particle free metallic inks can create the entire circuit trace and via structures to simulate and eliminate bulk electrolytic plating. The exposed final finish surface mount attachment pads or terminals can be plated or coated with conventional final finish materials or can be printed with appropriate metal or organic inks that are acceptable for solder reflow attachment of final assembled devices.

The subject matter discussed herein allows for the deposition of low-loss dielectric inks in a desired pattern that creates deposition regions for particle free metallic inks. The particle-free inks when cured typically deposit a metal film of approximately 1 to 3 microns thick. The intended process is to print multiple passes, with a curing step of thermal or argon atmospheric exposure or argon plus 5% hydrogen plasma atmospheric exposure such that each deposition layer is cured pure metal and each subsequent layer makes a makes a chemical bond to the previous layer, preferably with no demarcation or oxidation line. The depth of cure is subjective depending on the molecular particle free composition of metals such as Cu, Pd, Au, Ag, Pt, Ni etc.

Another aspect is to overcome the limitations of particle-based inks. The vast majority of 3D printed circuit applications utilize particle-based silver inks, with some copper or gold used in some situations. The bulk resistivity of these particle-based inks when cured is much higher than a pure bulk conductor as the electrical path is made up of touching points between adjacent particles. Thes particle-based inks at times have a polymer binder that holds the particles together and in position, and in cases the particle based inks are sintered either with a thermal exposure or an intense photonic exposure that heats and partially melts the metal particles quickly such that the adjacent polymer insulation is not damaged. This sintering operation can improve the conductivity to approach bulk metal, but does have artifacts and non-smooth surfaces and cross section which is not acceptable for high speed applications. The process described with respect to FIG. 7 combines the benefits of particle-based inks combined with particle-free based inks where the particle-based ink can provide a larger volume of conductor materials and the particle-free ink can saturate the particle-based deposition and fill the gaps to a degree to create a compost that replicates a more bulk metal deposition. This deposition can be sequential where particle-based ink, preferably aqueous based, is printed and cured or dried and particle-free metal ink is deposited in liquid form such that the field of particles is saturated and encapsulated. When the particle-free ink is cured the molecular deposition of metal creates a composite cross-section that is intended to be more like bulk metal and more conductive than the particle-based ink alone. This deposition can also be a combined solution with both inks deposited at the same time.

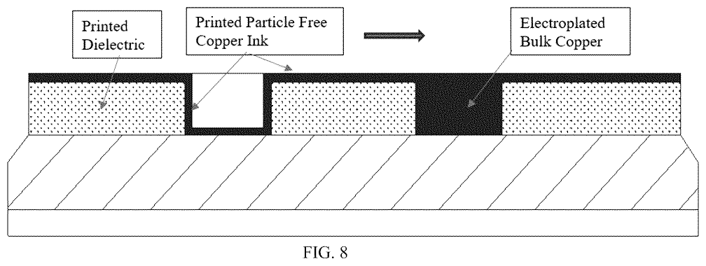

FIG. 8 is a cross-sectional view of another example circuit structure, in which the platforms of FIGS. 1-3 provide a hybrid approach where the particle-free metal inks are used as an electroplating catalyst or seed layer to initiate conventional electrolytic plating or enhance electroless plating. The use of copper ink is important for post plating etch capability, where if a vertical via connection is to be electroplated a palladium based ink is acceptable with limited overspray or stray palladium deposits.

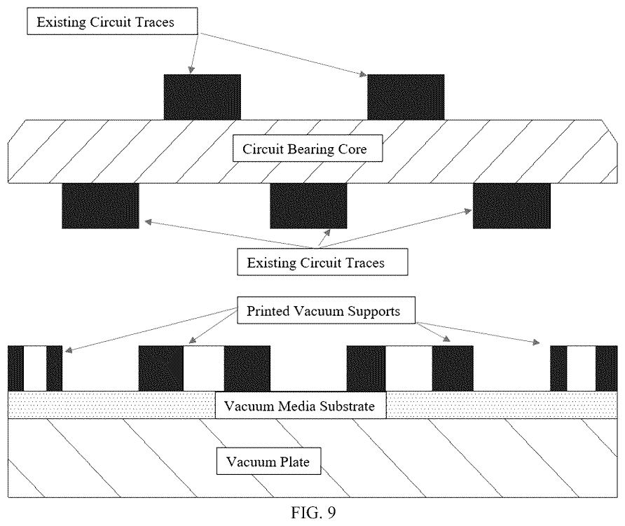

FIG. 9 is a cross-sectional view of an example stage in a process of printing using the platforms of FIGS. 1-3. These platforms can also address the limitations of current 3D printed circuit platforms that print onto a base substrate with circuits printed onto the stack in a one sided termination construction. The platforms enable “Print on core” or Print on mask” construction where a predefined circuit constructed of ABF, LCP, polyimide, FR4, low loss dielectric film or any other printed circuit film or laminate is placed into the invention platform with dielectric ink printed between pre-existing circuit traces and features on one side and inverted to print on the opposite side with the process repeated with localized optical alignment to previous features. In some cases with low to medium viscosity materials, the surface may be flooded to cover the preexisting traces with enough liquid flow to fill between the traces, or the spaces can be printed with dielectric directly.

FIG. 9 illustrates a Print on Core construction, where a prefabricated core of LCP, ABF, Polyimide, FR4 or any other conventional printed circuit construction is created with conventional means to provide circuits on one side or both sides of the structure. FIG. 9 reflects a typical basic structure of traces both sides, with vertical via connections omitted from the drawing for simplicity. This type of core is often present in all types of conventional construction and may be power-ground layers for example.

The platforms provide the ability to print on both sides of a core. Conventional 3D circuit printers print onto a substrate or build plate and typically print only upwards on one side. With a print on core construction, a sacrificial support that consists of a permeable layer that allows vacuum pass through such as a mesh, melt-blown, spun bond or other similar material is processed with supports printed as the negative of the circuit pattern also with vacuum pass through such that the core is firmly held flat in the platform.

An advantage of printing the support structure with the same system as used to print the circuit structure is that it enables optical alignment of features to previous or subsequent printing of the support structure. Many cores or substrates may be of flexible nature so proper support to avoid sagging or non-planar regions is desired. As one side is printed with support, the core is reversed or flipped to the other side with an appropriate support structure in place to enable double sided printing of the desired circuit stack. There may be instances where the substrate or core alone has sufficient support to maintain a flat planar surface for printing and sacrificial support may not be required.

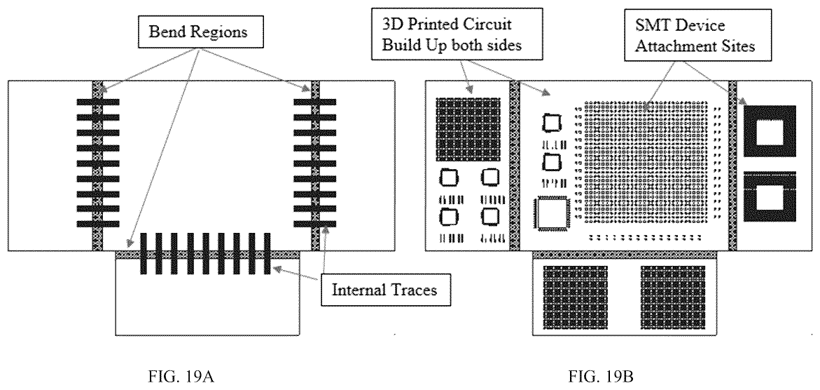

FIGS. 19A and 19B are examples of rigid-flex PCBs created using the Print on Core process described herein. Rigid-Flex is a hybrid construction where rigid regions where devices are soldered are connected with circuits or traces that are internal or embedded within the circuit stack, and the regions between the rigid sections are flexible. These flexible regions are typically occupied by a limited number of circuit layers such that when they bend the circuitry does not separate, break, or crack and the flexible regions allow for electrical connection as desired between the rigid regions. This configuration is popular for assemblies that are non-planar or have a desired shape that can be oriented without the need for additional connectors between rigid circuits. Conventional rigid-flex circuits typically contain a flexible core that is laminated with rigid material such as FR4 and vias are created to connect the various layers required by the design. This lamination method typically has regions cut out from a continuous layer such that when laminated the rigid regions are located appropriately on the flexible core. In some cases, the flexible bend regions can be scribed, ablated, or routed away to result in a bendable region that is thin enough to flex without breaking the internal circuits.

The platforms described herein can be used to create such a rigid-flex PCB as shown in FIGS. 19A and 19B using AME and the Print on Core process described herein. To create such a rigid-flex PCB, a flexible core having appropriate circuitry for the resulting rigid-flex PCB can be loaded into a printing platform described herein. The flexible core is made from LCP, Polyimide, or other flexible substrate material. The flexible core contains the appropriate circuitry for the designs, with circuits and traces that pass through the desired regions that will eventually be bendable and remain flexible. The printing platform can then add material onto select regions of both sides of the flexible core to form the rigid-flex PCB. The onboard optical system can align to features on the core with local scaling to provide the most accurate alignment of new deposition to pre-existing features on the flexible core. The alignment process can identify and align with one or more fiducials created for the purpose of alignment on the core. The regions onto which additional material layers are printed using the platforms described herein are the rigid regions. The core structure is flipped as needed to print both sides of the build-up circuit stack. The AME printing process takes the place of lamination-based processes used to form the rigid regions in traditional fabrication. Instead, the rigid regions are directly printed onto the core up to the surface-mount technology (SMT) device mask layer. The flexible core is an inner (e.g., proximate the middle) layer of the resulting PCB.

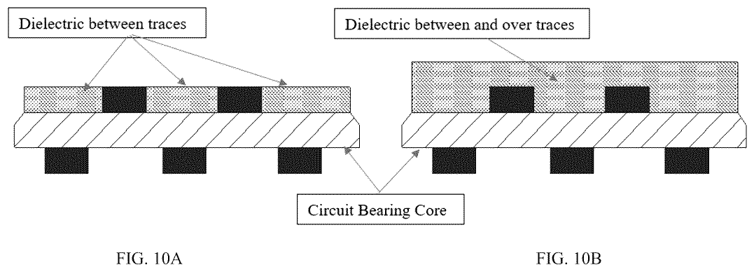

FIGS. 10A and 10B are cross-sectional views of example circuit structures printed with any of the platforms of FIGS. 1-3 to create an extremely flat print surface as the precision if the deposition is a key aspect of the platform. The platforms can be used to deposit the next dielectric layers. The onboard optical system can align to features on the core with local scaling to provide the most accurate alignment of new deposition to pre-existing features. The inkjet head can print between traces to fill the spaces (FIG. 10A) provided the space is larger than the resolution and registration tolerance of the inkjet which is approximately 25 microns. The aerosol head has tolerance limitations as well, with a smaller deposition target approximately 10 microns. The dispenser head can deposit higher viscosity materials and can have a nozzle size of 25 to 50 microns in some configurations, or microns depending on the chosen dispenser type. The extrusion head can deposit Liquid Crystal Polymer thermoplastic within the tolerance and registration of the filament or pellet extrusion. In some cases (FIG. 10B) the deposition may fill in between the traces as well as provide dielectric over the traces in a two-step or one-step process depending on the flow of the material and the aspect ratio of the traces and circuit features.

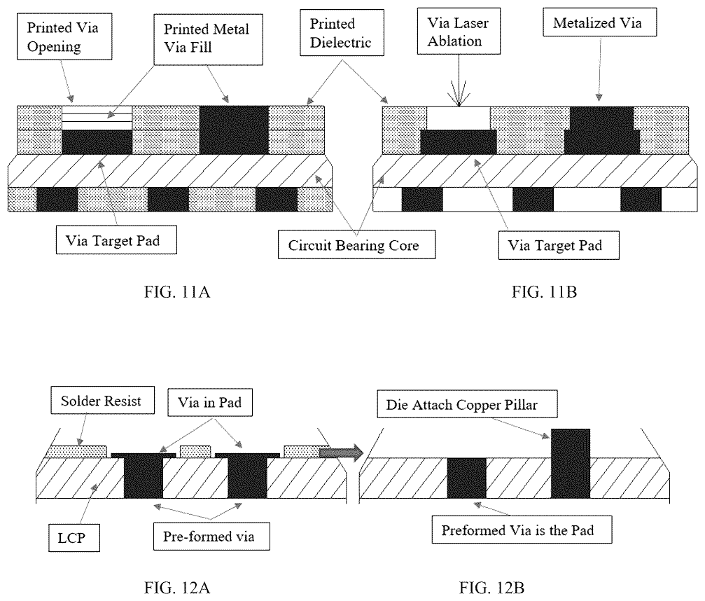

FIGS. 11A and 11B are cross-sectional views of example stages in printing circuit structures with the platforms of FIGS. 1-3. With a vertical metal via connection, a via target pad is typically present to provide a connection point from one layer of circuitry to the next. The printing platforms of FIGS. 1-3 can deposit the next dielectric layer (FIG. 11A) onto the previous layer and leave a gap or hole in the print pattern directly above the via target pad. This cavity can then accept the metallization process to create a full metal via. In the event the dielectric layer resides between the traces and above the via target pads, the laser ablation tool can drill or remove the dielectric material above the pad (FIG. 11B), with the pad preventing laser beam penetration beyond the pad.

In conventional printed circuit construction, vertical metal connections are typically accomplished with a drilled hole that is plated with copper. One of these types of holes is called a micro-via or blind via, where there is a copper pad under the dielectric layer that has a diameter larger than the desired via hole size. This pad is called a capture pad and it serves as a stop for a laser beam that is used for drilling or ablating the dielectric material as the laser will remove the dielectric material at a low power setting but not go through the metal capture pad. In the case of the printed 3D circuits made by today's printing platforms, the printing pattern typically leaves a hole in the print pattern that corresponds to the metal trace beneath the layer being printed. This hole is then filled with metal ink like the print for circuit traces. In this case, the capture pad is helpful to have a larger target to print metal onto, but the metal is not needed to stop the laser. The subject matter discussed herein platform the option to include a laser ablation source that is unique to a printing system. In one capability example, a circuit with pre-existing circuit patterns is placed into the platform and the surface of the circuit is sprayed, inkjet, or coated with low loss dielectric that flows between the circuits and may also cover the circuits to create the next dielectric layer. In this case, the laser tool is necessary to ablate the dielectric over the previous metal trace or capture pad. The platform has a plasma atmosphere tool that can be used to treat the ablated hole and remove any debris or carbon deposits as a result of the laser ablation, and the metal ink deposition can fill the hole and create the vertical electrical connection from the previous metal layer to the next. This structure can also have the side walls of the vias coated with metal and electrically connected to a seed layer on the top surface of the exposed dielectric such that an electrolytic plating bus can be connected to electroplate the vias full of copper and post plate etch the surface copper.

FIGS. 12A and 12B are cross-sectional views of other example stages in creating a circuit structure using the platforms of FIGS. 1-3. The principle of Print on Mask is somewhat of a reversal of the normal sequence, where layers are built and the final layer where components are attached is finished last as an outer exposed layer that is plated or coated with an acceptable solderable surface. The common practice is to apply solder mask to the final metal layers and image and develop openings in the mask that expose the surface mount terminations while creating a non-solderable material between the terminations such that molten solder will not wet and bridge or short the terminations or component terminals. This sequence is generally a limitation for conventional fabrications as the solder mask image is often difficult to register to the desired features and very fine interconnects can be too small for solder mask imaging or developing. The Print on Mask principle is a enabled by the platform invention, whereas with the Print on Core principle, a dielectric layer that already bears the terminations of the final surface mount solder pattern in a single dielectric layer that when placed in the platform has exposed vertical interconnection points in place ready for printing. This principle removes the limitation of conventional printer systems limited to typically one-sided circuit stacks, where the mask layer already has one side of the stack intact.

FIG. 12A illustrates a simple section of an entire circuit pattern mask layer, where the surface mount pads are present in a via-in-pad configuration with a solid copper via supporting a surface mount pad. This configuration is typically called mask defined, and conventional solder mask may be present. FIG. 12B shows a structure where the via is the pad, with the desired entire surface mount pattern is contained within the single mask layer (preferably LCP), and solid mounting regions are plated within the layer. This configuration is typically called metal defined and the components will solder directly to the vias. In each case, the upper exposed metal surfaces are plated or coated with solderable final finish.

To Print on Mask, the platforms of FIGS. 1-3 are used to add layers and desired circuit patterns, vias, etc. to the layers shown in FIGS. 12A and 12B. The layers shown in FIGS. 12A and 12B can be formed by traditional non-AME methods such as masking, etching, and deposition to create the existing circuit patterns in the layers. Traditional non-AME methods may define geometries better than the AME processes described herein, which may be desired for an outer/exposed layer of a circuit board to with SMT components are to be mounted. Thus, the traditional non-AME methods can be used to create the layers shown in FIGS. 12A and 12B. The platforms described herein can then add to those layers to create additional layers underneath the outer/exposed layer. The circuit structures shown in FIGS. 12A and 12B would be flipped upside down, compared to how they are oriented in FIGS. 12A and 12B and additional layers would be added using AME processes with the platforms described herein. The onboard optical system in the printing platform can align to features on the existing circuit structure with local scaling to provide the most accurate alignment of new deposition to pre-existing features on the pre-existing circuit structures. The alignment process can identify and align with one or more fiducials created for the purpose of alignment on the existing layers. The additional layers will end up “underneath” the exposed outer layer of the resulting PCB. In this way, the Print on Mask process can be used to add additional layers underneath a pre-existing circuit board having a pre-existing outer/exposed surface. Although only a single layer is shown for the examples in FIGS. 12A and 12B, the pre-existing circuit structure can include an outer/exposed layer and one or more additional pre-existing layers “underneath” that layer. Regardless of how may layers are pre-existing, the Print on Mask process described herein can be used to add additional layers “underneath” the existing layers.

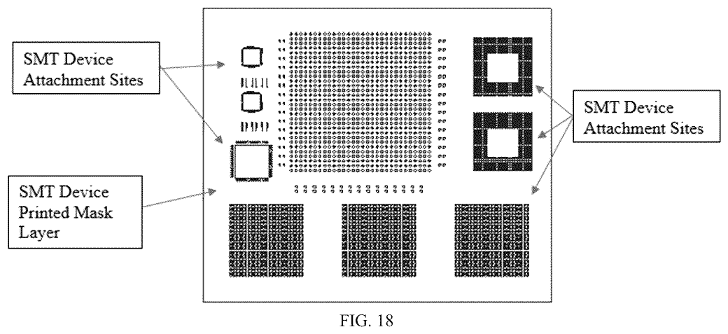

FIG. 18 is an example of an outer/exposed surface of an existing circuit structure onto which additional layers can be added underneath using the Print on Mask process described herein. The example surface includes pre-existing features for mounting of surface mount devices, such as BGAs, QFNs, QFPs, TSSOPs, Resistors, Capacitors and any number of different devices and components needed for the final assembly, with the SMT terminations in one layer.

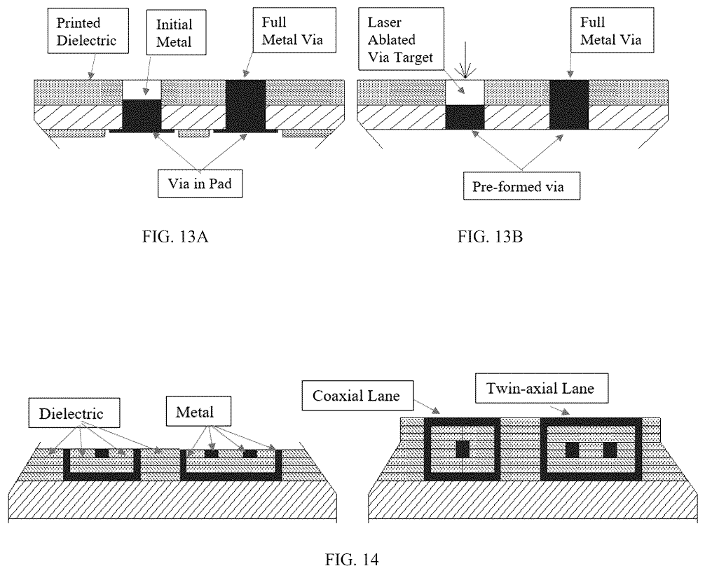

FIGS. 13A and 13B are cross-sectional views of other example circuit structures created using the Print on Mask principle, with the final finish surface of the mask face down on the printing platform. This configuration allows for sequential printing of subsequent layers that will stack on top of each other and eventually end at another mask layer printed as the final exposed layer for surface mount soldering of the desired complete assembly.

FIG. 13A illustrates a method where the dielectric is printed onto the mask layer with the print pattern leaving open the exposed metal of the pre-defined via. This exposed metal surface is then metalized per described. FIG. 13B illustrates a method where the next dielectric layer is contiguous and covers the exposed metal surface of the via. In this event, the laser ablation tool removes dielectric material above the via and the via target is metalized per the described sequence. The complete circuit stack is printed upward to the level of final termination layer exposed on the topside of the circuit stack. The exposed final surface mount pads are then coated with a protectant, plated or metalized with a solderable particle free metal ink.

Another unique aspect of the platforms is the ability to create a Print on Mask construction that has copper pillars that extend beyond the surface of the mask. This is very beneficial for very fine pitch device such as bare die that can be mounted onto the pillars, as well as add thermal management regions or high reliability posts for devices to solder to.

FIG. 14 is cross-sectional views of example stages in printing coaxial and twin axial signal lane structures that provide extreme signal isolation and eliminate cross talk. These embedded coaxial structures can also be turned vertical to create coaxial vias to the surface mount plane for very high performance applications. Traditional circuit fabrication typically adds a number of ground vias adjacent to high speed signal lines and vias to provide isolation and these via structures consume a relatively large area which fights against circuit density.

The left cross-section in FIG. 14 illustrates a patterning process where alternating positions of dielectric and metal are printed layer by layer as described, with a base metal layer at ground and selective deposition at the proper position on each layer pass creates a metal side wall tied to ground, with insulating dielectric positions adjacent to the metal positions. The sequence is repeated in multiple passes to complete the structure and cap with another plane tied to ground. The right cross-section of FIG. 14 illustrates a completed coaxial lane and completed twin-axial lane that in actual structural size is many times smaller than a conventional lane.

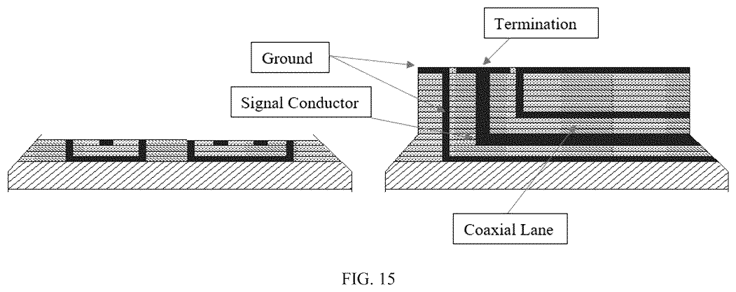

FIG. 15 is cross-sectional views of example stages in printing a coaxial structure with a vertical transition of the embedded coaxial or twin-axial lanes. To do so, the principle of FIG. 14 is shifted to continue the walls and center conductor vertically to the desired termination point internal to the stack or all the way to the surface mount pad terminations.

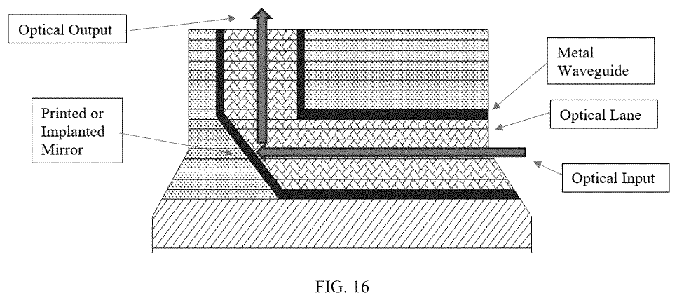

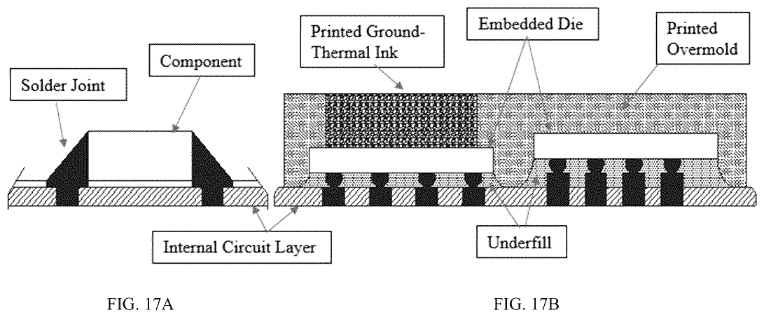

FIG. 16 is a cross-sectional view of another example structure printed with the platforms that includes a lane with an optical polymer dielectric to create an embedded optical transmission line, or optical plane if desired. A miniature mirror structure can be installed and positioned to bend or direct the photonic path and create an optical via in principle. This bean steering can be on the same plane or change in plane while the optical waveguide may also carry signal lines in the same space.

Another unique aspect of the platform invention is the ability to embed active and passive components within the circuit stack as it is being printed. For example, in a 10-layer circuit stack, the printing operation can provide a mounting layer at layer 6, stop the progression of printing, mount desired devices and then restart the printing process to encapsulate and embed active die, passive components, thermal or power management features etc. For RF-MW and high-speed wireless devices the embedded device can have topside or bottom side electrical and thermal interconnect by printing the metal inks and avoiding the potential for subjecting the die to current and voltage during a plating operation. In addition, an air cavity can be left over the active die and capped with a layer of LCP that is structured to provide a base for completing the printed circuit stack. The terminations at such a level look like final attachment terminals.

FIGS. 17A and 17B are cross-sectional views of example circuit structures created with the platforms illustrating a very basic example of mounting embedded devices on an internal circuit layer within the circuit stack. There are printer platforms that attempt to enable surface mount solder attachment of devices directly in the platform while the present platform does not contemplate in-system, attachment as these operations are best left to appropriate equipment and process sets especially when mounting bare die. FIG. 17A illustrates discrete component attachment such as capacitors, resistors etc. where they devices are soldered as with a normal assembly process. FIG. 17B illustrates direct die attachment in either flip chip, thermos-compression stud bump or even wire bond attachment. The substrate is placed back into the printing platform and aligned with the precision vision system. In some cases such as with RF-MW die, there are electrical connections on both sides of the die, one side being I/O terminations and other side being ground and thermal connection. The mounted die can be underfilled with the precision dispenser tool, and over molded with printed Liquid Crystal Polymer printed from the filament-pellet extruder tool. The thermal-ground plane connection can be metalized with the printed metal inks with the option to utilize a high metal content conductive particle ink from the dispense head since signal integrity is not critical with a ground-thermal electrical connection.

To expand upon the embedded die principle, the platforms enables the ability to apply particle free metal inks in select locations and surfaces to shield components within a self-contained module, or create metalized surfaces that act as antenna or filters for unwanted signals. The ability to discretely deposit metal features, and layers in the 3D printed matrix also provides a method for embedding security features and anti-tamper measures, embedded RFID and other functions that are not possible with conventional substrate fabrication and microelectronics assembly.

There are many benefits to the subject matter described herein. As high-speed circuit assemblies encounter smaller and smaller circuit geometries and spacing, conventional film or laminate based dielectric materials are challenged to meet impedance requirements due to commercially available thickness. In addition, lamination temperatures and pressures can drive mechanical and flatness issues when trying to fill in between circuit traces and provide a strong mechanical bond between layers. The use of low loss dielectric materials in liquidous or ink form can provide a platform to print the dielectric layers in place rather than laminate, as well as provide a low temperature and low-pressure bonding agent with the spaces between the traces already filled and leveled by the flow if the printing process. The low loss dielectric materials can also be loaded with particulates of LCP, PTFE, Ceramic etc. to enhance the electrical and mechanical performance into a composite presenting the best properties of the aggregate mixture in very thin layers while maintaining impedance environments. The low loss dielectric materials can also be used as a final finish layer eliminating the need for lossy solder mask and registration issues with imaging solder mask locations. The use of particle free inks can reduce the need for plating operations and chemistries, and the ability to embed devices and connect and overmold them directly in the platform with printed LCP enables a hermetic or environmental protected substrate with internal circuits and devices. The 3 levels of platform complexity combine the operations normally seen in individual stand-alone systems, which can still be used to fill capability gaps depending on the level of sophistication of the platform.

There is currently no printing platform capable of printing high speed, multi-layer, double sided, high density 3D circuits, with ability to mount, embed and overmold passive components and active die at any layer within a circuit stack. The proposed invention provides a multi-level platform architecture that is focused on the desired material sets of low loss dielectrics which have not been available for 3D printing, and particle free metallic inks that can be deposited in a precise manner as an alternative to conventional electroless and electrolytic plating.

The platforms herein are also supported by the ability to print very precision circuits on both sides of a substrate by installing a substrate that has pre-existing circuits, patterns, vias in a Print on Mask or Print on Core configurations as well as sacrificial support members that enable a vacuum table to hold flexible materials flat within the system during printing.

There are many benefits to the subject matter herein taking advantage of the additive material deposition principles of 3D printed circuits and Additive Manufactured Electronics manufacturing methods. Printing directly onto a predefined Mask layer or predefined Core layer to complete the desired circuit stack enables complex multi-layer circuit stacks with the ability to mount devices on both sides while conventional 3D printed circuits only have SMT mounting terminations on the outermost top layer. The subject matter herein also has significant advantages over conventional laminated printed circuit fabrication, especially for rigid-flex applications. The ability to 3D print dielectrics and metal inks complemented with electrolytic plating where applicable drastically improves the environmental and capital equipment impact with direct write and deposition of materials only in the desired locations.

What is claimed is:

1. A method of creating a printed circuit board (PCB), the method comprising:
providing a core having one or more fiducials thereon and including a first one or more circuit structures;
aligning one or more components of a printer with the one or more fiducials based on one or more images captured of the core with an optical camera of the printer;
printing with the one or more components of the printer, a first dielectric layer on a first side of the core;
printing with the one or more components of the printer, a second one or more circuit structures in the first dielectric layer;
printing with one or more components of the printer, a second dielectric layer on a second side of the core, the second side reverse of the first side; and
printing with one or more components of the printer, a third one or more circuit structures in the second dielectric layer on the second side of the core.

2. The method of claim 1, comprising:
laminating a plurality of conductive layers together with one or more prepreg layers between adjacent conductive layers to form the core.

3. The method of claim 1, wherein the one or more components include one or more of:
an inkjet head;
an aerosol print head;
a dispense head;
a UV source;
an Argo or Argon/Hydrogen plasma head;
a height senor; and
a drop watch camera.

4. The method of claim 1, wherein the core is a flexible circuit bearing structure configured to bend without damaging the first one or more circuit structures.

5. The method of claim 4, wherein the first dielectric layer, the second one or more circuit structures, the second dielectric layer, and the third one or more circuit structures are disposed in one or more rigid regions of the PCB, which is a rigid-flex PCB having one or more flexible regions which are distinct from the one or more rigid regions.

6. The method of claim 5, wherein printing the first dielectric layer, the second one or more circuit structures, the second dielectric layer, and the third one or more circuit structures includes avoiding printing in the one or more flexible regions.

7. The method of claim 1, comprising:
printing with the one or more components of the printer, one or more additional dielectric layers and circuit structures on the first side and the second side of the core.

8. A method of creating a printed circuit board (PCB), the method comprising:
providing a circuit structure having a mask layer with one or more fiducials thereon and defining a plurality of pads for mounting of one or more surface mount technology (SMT) components on a first side thereof;
aligning one or more components of a printer with the one or more fiducials based on one or more images captured of the first side of the circuit structure with an optical camera of the printer;
printing with the one or more components of the printer, a first dielectric layer on a second side of the circuit structure, the second side reverse of the first side; and
printing with the one or more components of the printer, a first one or more circuit structures in the second dielectric layer on the second side of the circuit structure.

9. The method of claim 8, comprising:
laminating a plurality of conductive layers together with one or more prepreg layers between adjacent conductive layers to form the circuit structure having a mask layer.

10. The method of claim 8, wherein the one or more components include one or more of:
an inkjet head;
an aerosol print head;
a dispense head;
a UV source;
an Argo or Argon/Hydrogen plasma head;
a height senor; and
a drop watch camera.

11. The method of claim 8, comprising:
printing with the one or more components of the printer, one or more additional dielectric layers and circuit structures on the second side of the circuit structure.

12. The method of claim 8, comprising:
mounting one or more SMT components to the plurality of pads.
